(19) United States
(12) Patent Application Publication
(10) Pub. No.: US 2015/0069598 A1
(43) Pub. Date: Mar. 12, 2015

(54) HEAT DISSIPATION CONNECTOR AND METHOD OF MANUFACTURING SAME, SEMICONDUCTOR DEVICE AND METHOD OF MANUFACTURING SAME, AND SEMICONDUCTOR MANUFACTURING APPARATUS

(71) Applicant: Kabushiki Kaisha Toshiba, Tokyo (JP)

(72) Inventors: Koji Tamura, Himeji-Shi (JP); Nobuyuki Sato, Nonoichi-Shi (JP); Nobuhiro Shingai, Himeji-Shi (JP); Shinya Ozawa, Kanazawa-Shi (JP); Takeru Matsuoka, Himeji-Shi (JP); Hideki Okumura, Nonoichi-Shi (JP)

(73) Assignee: KABUSHIKI KAISHA TOSHIBA, Tokyo (JP)

(21) Appl. No.: 14/199,622

(22) Filed: Mar. 6, 2014

(30) Foreign Application Priority Data
Sep. 6, 2013 (JP) 2013-185635

(51) Int. Cl. H01L 23/40; H01L 21/673; H01L 21/56

(52) U.S. Cl. CPC H01L 23/40; H01L 21/565; H01L 21/673
USPC 257/713; 438/122; 29/739

(57) ABSTRACT

In one embodiment, a heat dissipation connector mounted on a semiconductor chip and sealed up with a molding resin along with the semiconductor chip and a lead frame includes a heat dissipation portion configured to have a block shape, and have an upper face exposed out of the molding resin. The connector further includes a connecting portion configured to extend from a first side face of the heat dissipation portion, and electrically connect an electrode arranged on the semiconductor chip to the lead frame. The heat dissipation portion and the connecting portion are integrally made of the same metal sheet.

### CROSS REFERENCE TO RELATED APPLICATION

This application is based upon and claims the benefit of priority from the prior Japanese Patent Application No. 2013-185635, filed on Sep. 6, 2013, the entire contents of which are incorporated herein by reference.

### FIELD

Embodiments described herein relate to a heat dissipation connector and a method of manufacturing the same, a semiconductor device and a method of manufacturing the same, and a semiconductor manufacturing apparatus.

### BACKGROUND

A semiconductor chip, which generates a great deal of heat, is sealed up with a molding resin along with a heat dissipation disk for releasing the heat from the semiconductor chip. The heat dissipation disk is stacked on the semiconductor chip via a connector component, and the upper face of the heat dissipation disk is exposed out of the molding resin.

If the semiconductor chip is reduced in size in order to miniaturize a semiconductor device, the connector component and the heat dissipation disk also need to be reduced in size correspondingly to the size of the semiconductor chip. However, it is increasingly difficult to precisely stack the heat dissipation disk on the connector component if the connector component is made smaller. This may reduce the manufacturing yield of the semiconductor device.

### BRIEF DESCRIPTION OF THE DRAWINGS

FIGS. 1A and 1B are drawings of a semiconductor device of a first embodiment;

FIGS. 2A and 2B are drawings of a heat dissipation connector of the first embodiment;

FIGS. 3A to 3C are drawings for describing a method of manufacturing the heat dissipation connector of the first embodiment;

FIG. 4 is a flowchart showing a method of manufacturing the semiconductor device of the first embodiment;

FIG. 5 is a schematic view of a semiconductor manufacturing apparatus of the first embodiment;

FIGS. 6A and 6B are drawings of a heat dissipation connector of a modified example of the first embodiment;

FIGS. 7A and 7B are drawings of a heat dissipation connector of a second embodiment;

FIGS. 8A to 8C are drawings for describing a method of manufacturing the heat dissipation connector of the second embodiment; and

FIGS. 9A and 9B are drawings of a heat dissipation connector of a modified example of the second embodiment.

### DETAILED DESCRIPTION

Embodiments will now be explained with reference to the accompanying drawings. The present invention is not limited to these embodiments. Common components are denoted by common reference numerals throughout the drawings, and duplicate descriptions of these components are omitted. The drawings are schematic views used to facilitate the description and understanding of the invention, and may therefore differ from actual devices in shape, dimension, ratio and the like in some places. Design changes can be made to these devices as appropriate by taking into consideration the following description and known technology. In the following embodiments, a vertical direction of a semiconductor chip indicates a relative direction when a surface of the semiconductor chip where semiconductor elements are arranged is faced up, and may therefore differ from a vertical direction based on the gravitational acceleration in some cases.

In one embodiment, a heat dissipation connector mounted on a semiconductor chip and sealed up with a molding resin along with the semiconductor chip and a lead frame includes a heat dissipation portion configured to have a block shape, and have an upper face exposed out of the molding resin. The connector further includes a connecting portion configured to extend from a first side face of the heat dissipation portion, and electrically connect an electrode arranged on the semiconductor chip to the lead frame. The heat dissipation portion and the connecting portion are integrally made of the same metal sheet.

### First Embodiment

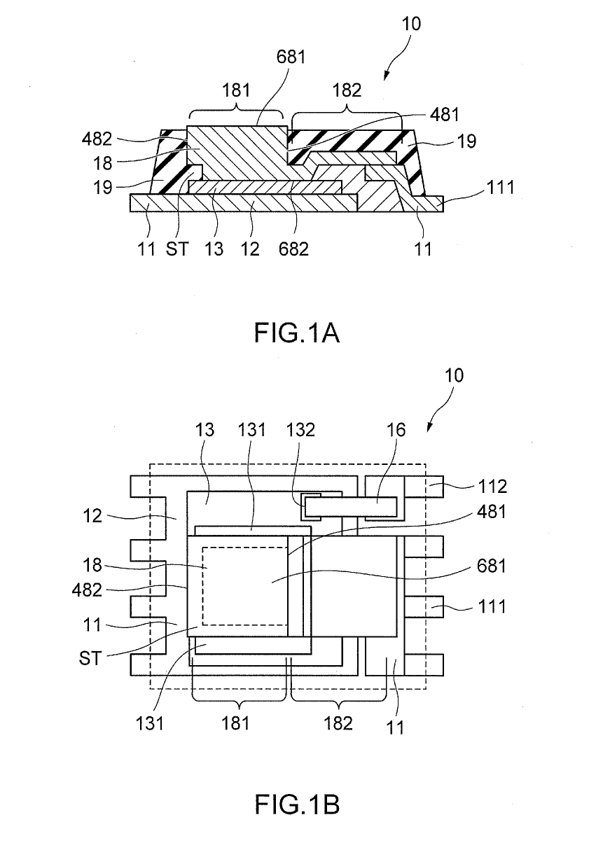

FIGS. 1A and 1B are drawings of a semiconductor device 10 of a first embodiment.

FIG. 1A illustrates a cross section of the semiconductor device 10 of the first embodiment, and FIG. 1B illustrates an upper face of the semiconductor device 10. In FIG. 1B, a molding resin 19 is omitted from the illustration for the sake of clarity.

The semiconductor device 10 includes a lead frame 11, a semiconductor chip 13, a connector 16, a heat dissipation connector 18, and the molding resin 19.

The molding resin 19 seals up the lead frame 11, the semiconductor chip 13, the connector 16, and the heat dissipation connector 18. An upper face 681 of the heat dissipation connector 18 is exposed out of the molding resin 19.

The lead frame 11 includes an island portion 12, and a first and second terminal portions 111 and 112 which are separated from the island portion 12. The lead frame 11 is made of an electrical conductor and formed with, for example, low-resistance metal. The island portion 12 is a mounting portion on which the semiconductor chip 13 is mounted. The first terminal portion 111 and the second terminal portion 112 are electrically connected to the first electrode 131 and the second electrode 132 of the semiconductor chip 13.

The semiconductor chip 13 is mounted on the island portion 12 and includes the first electrode 131 and the second electrode 132. The type of semiconductor chip 13 is optional, and therefore is not limited in particular.

The connector 16 is located on the second electrode 132 and the second terminal portion 112 in order to electrically connect the second electrode 132 and the second terminal portion 112. The connector 16 is also made of an electrical conductor and formed with, for example, low-resistance metal.

The heat dissipation connector 18 is located on the first electrode 131 of the semiconductor chip 13 and the first terminal portion 111 in order to electrically connect the first electrode 131 and the first terminal portion 111. The heat dissipation connector 18 is formed of metal (for example, copper) having excellent electrical conductivity and thermal conductivity. Accordingly, this heat dissipation connector 18 has the function of not only discharging heat from the semiconductor chip 13 to outside the semiconductor device 10 but also electrically connecting the first electrode 131 and the first terminal portion 111.

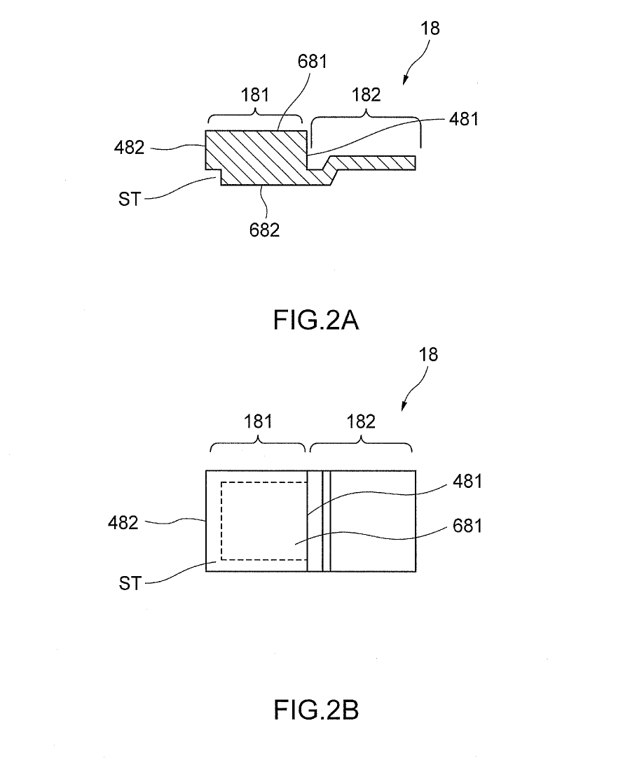

FIGS. 2A and 2B are drawings of the heat dissipation connector 18 of the first embodiment.

FIG. 2A illustrates a cross section of the heat dissipation connector 18, and FIG. 2B illustrates an upper face of the heat dissipation connector 18.

The heat dissipation connector 18 includes a heat dissipation portion 181 for discharging heat, and a connecting portion 182 for electrically connecting the first electrode 131 and the first terminal portion 111. The heat dissipation portion 181 and the connecting portion 182 are integrally formed of a metal sheet. That is, the heat dissipation portion 181 and the connecting portion 182 in the first embodiment are not individually formed as two separate components but are integrally formed as one heat dissipation connector 18.

In addition, the heat dissipation portion 181 has a block shape. In the semiconductor device 10, the upper face 681 of the heat dissipation portion 181 is exposed out of the molding resin 19, and the heat of the semiconductor chip 13 is discharged to outside the semiconductor device 10 from this surface (see FIG. 1A).

The connecting portion 182 is a sheet-like portion extending from a side face 481 of the heat dissipation portion 181, and a part of the connecting portion 182 is bent. In the semiconductor device 10, the connecting portion 182 extends up to the first terminal portion 111 to electrically connect the first electrode 131 and the first terminal portion 111 (see FIG. 1A).

The heat dissipation portion 181 includes a side face 482 located on an opposite side of the side face 481. The side face 482 has a step ST, and a lower region of the side face 482 (which is on the semiconductor chip 13 side) is recessed inward compared with an upper region of the side face 482 (see FIG. 1A). That is, the step ST is provided in a lower end portion of the side face 482 which is on the semiconductor chip 13 side. In addition, two side faces of the heat dissipation portion 181 other than the side face 481 have steps ST, as similar to the side face 482. Accordingly, a lower face 682 (a surface in contact with the semiconductor chip 13) of the heat dissipation portion 181 is narrower than the upper face 681 of the heat dissipation portion 181, and narrower than the semiconductor chip 13 as well.

As described above, the heat dissipation portion 181 and the connecting portion 182 in the first embodiment are integrated with each other to form one heat dissipation connector 18. Accordingly, if the heat dissipation connector 18 can be located on the semiconductor chip 13 and the first terminal portion 111 so as to electrically connect the first electrode 131 and the first terminal portion 111, the position of the heat dissipation portion 181 fixes for itself. The heat dissipation portion 181 therefore does not become displaced from the connecting portion 182. Consequently, it is possible to prevent a short circuit between the heat dissipation portion 181 and another connector (for example, the connector 16) and improve the manufacturing yield of the semiconductor device 10.

If it is assumed that the heat dissipation portion 181 and the connecting portion 182 are two separate components, it is necessary in the steps of manufacturing the semiconductor device 10 not only to locate the connecting portion 182 on the semiconductor chip 13 and the first terminal portion 111, but also to stack the heat dissipation portion 181 on the connecting portion 182. In addition, if the connecting portion 182 is reduced in size, it is increasingly difficult to precisely locate the heat dissipation portion 181 on the connecting portion 182. If the heat dissipation portion 181 is stacked on the connecting portion 182 in a position displaced from a correct position of the heat dissipation portion 181, the heat dissipation portion 181 may come into contact with other connectors and cause a short-circuit. It is therefore conceivable to make the heat dissipation portion 181 smaller so as to avoid contact with other connectors even if the heat dissipation portion 181 becomes displaced. However, the heat dissipation efficiency of the heat dissipation portion 181 decreases if the heat dissipation portion 181 is made smaller.

On the other hand, according to the first embodiment, the heat dissipation portion 181 and the connecting portion 182 are integrated with each other, and therefore the heat dissipation portion 181 needs not to be aligned with the connecting portion 182. In addition, the heat dissipation portion 181 needs not to be made smaller. Consequently, it is possible to improve the manufacturing yield of the semiconductor device 10 and the heat dissipation efficiency of heat dissipation portion 181.

In addition, the heat dissipation connector 18 of the first embodiment includes the step ST in the side face 482. Consequently, when the heat dissipation connector 18 is stacked on the semiconductor chip 13, a space (gap or trench) is formed in a part of the outer edge of the lower face 682 of the heat dissipation connector 18 by the step ST of the side face 482 and a surface of the semiconductor chip 13. When the heat dissipation connector 18 is bonded to the semiconductor chip 13 by using a conductive adhesive agent such as solder, the excessive conductive adhesive agent stays in this space due to the effect of, for example, capillary force. Accordingly, it is possible to prevent the conductive adhesive agent from spreading outside the semiconductor chip 13.

If any excessive conductive adhesive agent protrudes out of the semiconductor chip 13 and spreads up to the lead frame 11, a short-circuit may be generated between the semiconductor chip 13 and the lead frame 11 via the conductive adhesive agent.

However, it is possible in the first embodiment to prevent such a malfunction by providing the step ST in the side face 482 of the heat dissipation portion 181. The effect of the step ST of the side face 482 holds true for steps ST provided on other side faces as well.

(1) Method of Manufacturing Heat Dissipation Connector

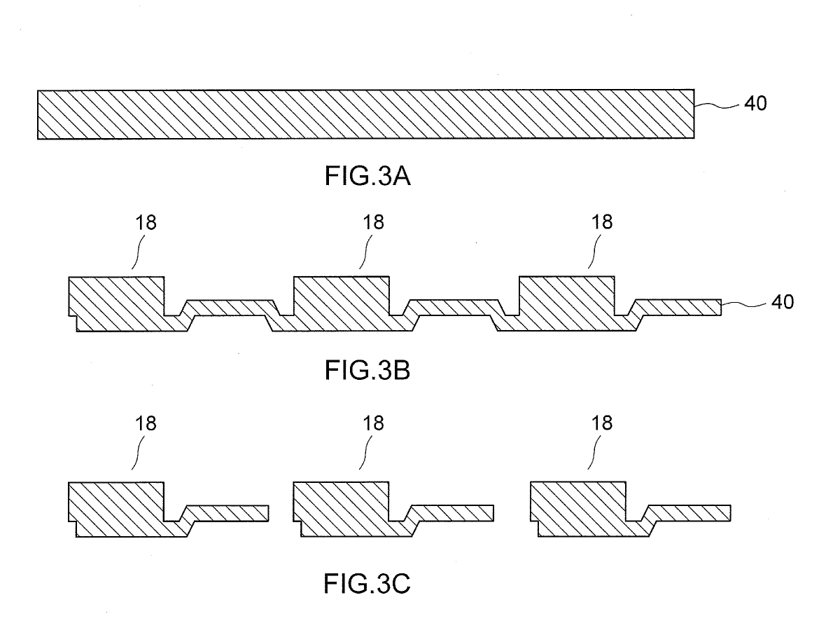

FIGS. 3A to 3C are drawings for describing a method of manufacturing the heat dissipation connector 18 of the first embodiment.

FIGS. 3A to 3C are cross-sectional views in respective steps of the method of manufacturing the heat dissipation connector 18.

As illustrated in FIG. 3A, a metal sheet 40 is prepared. Continuous heat dissipation connectors 18 as illustrated in FIG. 3B are then formed by pressing a metal mold against the metal sheet 40.

The heat dissipation connectors 18 are then cut apart as illustrated in FIG. 3C. The heat dissipation connector 18 described above can be obtained in this way.

The continuous heat dissipation connectors 18 may be formed by pushing the metal sheet 40 between two rolls with trenches opened on their surfaces, instead of pressing the metal mold against the metal sheet 40.

(2) Method of Manufacturing Semiconductor Device

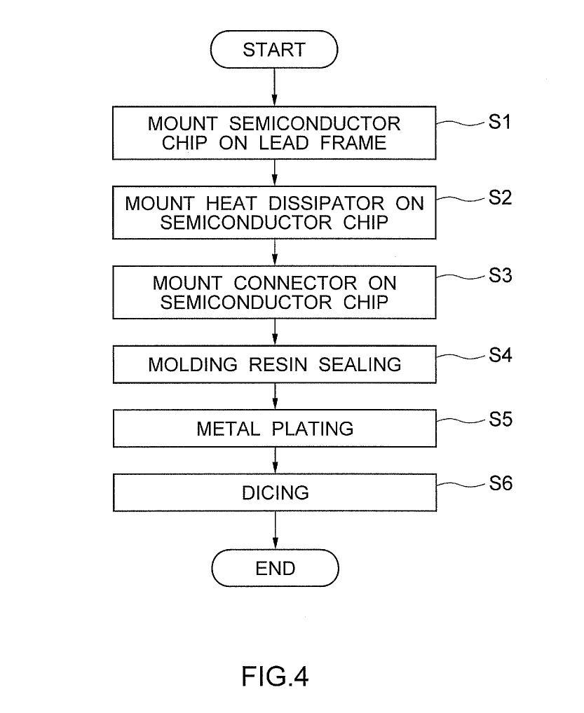

FIG. 4 is a flowchart showing a method of manufacturing the semiconductor device 10 of the first embodiment.

In step S1, the semiconductor chip 13 is mounted on the island portion 12 of the lead frame 11 by using a conductive adhesive agent such as solder.

In step S2, the heat dissipation connector 18 is mounted on the first electrode 131 of the semiconductor chip 13 and on the first terminal portion 111 of the lead frame 11 by using a conductive adhesive agent. As described above, the heat dissipation portion 181 and the connecting portion 182 in the first embodiment are integrated with each other and formed into one heat dissipation connector 18. Accordingly, if the heat dissipation connector 18 can be located on the semiconductor chip 13 and the lead frame 11 so as to electrically connect the first electrode 131 and the first terminal portion 111, the heat dissipation portion 181 does not become displaced from the connecting portion 182. In addition, since the step ST is provided on the side face 482 of the heat dissipation connector 18 as described above, the excessive conductive adhesive agent can be retained in a space formed with the step ST when the heat dissipation connector 18 is stacked on the semiconductor chip 13 by using the conductive adhesive agent.

In step S3, the connector 16 is mounted on the second electrode 132 and the second terminal portion 112 by using a conductive adhesive agent.

In step S4, the lead frame 11, the semiconductor chip 13, the connector 16, and the heat dissipation connector 18 are sealed up with the molding resin 19. At this time, these components are sealed up so as to expose the upper face 681 of the heat dissipation portion 181 out of the molding resin 19, thereby making it possible to discharge the heat from the semiconductor chip 13 out of the semiconductor device 10 via the upper face 681. In addition, the excessive molding resin 19 is removed.

In step S5, portions of the island portion 12 and the first and second terminal portions 111 and 112 which are exposed out of the molding resin 19 are metal-plated.

In step S6, a plurality of semiconductor devices 10 coupled by the lead frame 11 are cut apart (divided into individual pieces).

Consequently, the respective semiconductor devices 10 are completed.

According to the first embodiment, the heat dissipation portion 181 and the connecting portion 182 are integrated with each other to configure one heat dissipation connector 18. For this reason, when the heat dissipation connector 18 is mounted on the semiconductor chip 13 and the lead frame 11, it is sufficient to arrange the heat dissipation connector 18 so that the connecting portion 182 electrically connects the first electrode 131 and the first terminal portion 111, and it is not necessary to align the heat dissipation portion 181 with the connecting portion 182. It is therefore possible to improve the manufacturing yield of the semiconductor device 10.

In addition, according to the first embodiment, the step ST is provided on the side face 482 of the heat dissipation connector 18. Therefore, the excessive conductive adhesive agent can be retained in a space formed by the step ST when the heat dissipation connector 18 is stacked on the semiconductor chip 13. Accordingly, possible malfunctions can be prevented even if the conductive adhesive agent is oversupplied.

(3) Semiconductor Manufacturing Apparatus

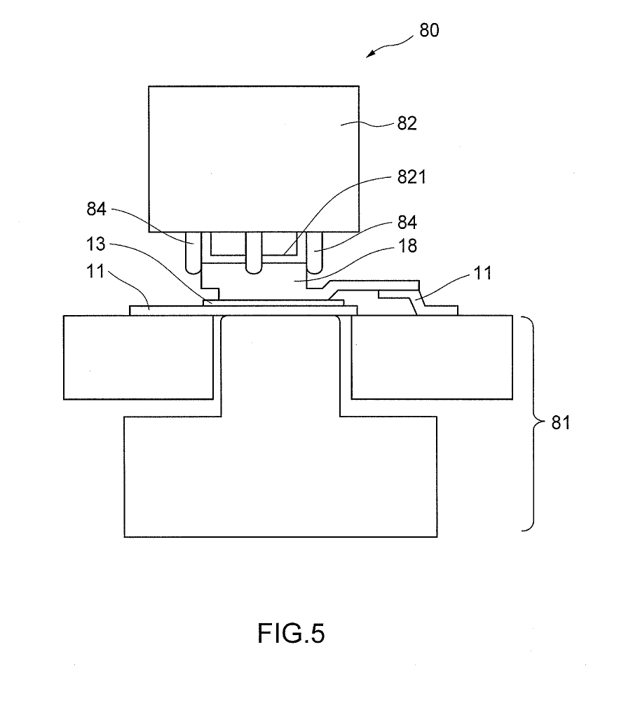

FIG. 5 is a schematic view of a semiconductor manufacturing apparatus 80 of the first embodiment. The semiconductor manufacturing apparatus 80 is used to mount the heat dissipation connector 18 on the semiconductor chip 13 and the lead frame 11 in step S2 discussed above.

The semiconductor manufacturing apparatus 80 includes a stage 81 for holding the lead frame 11 mounted with the semiconductor chip 13, and a transfer module 82 for adsorbing the heat dissipation connector 18 to transfer the heat dissipation connector 18 onto the semiconductor chip 13.

The transfer module 82 has an adsorbing surface 821 for adsorbing the heat dissipation connector 18. A plurality of guides 84 for guiding the heat dissipation connector 18 to a predetermined position on the adsorbing surface 821 are arranged on the adsorbing surface 821. The plurality of guides 84 are configured to guide the heat dissipation portion 181 of the heat dissipation connector 18 to the adsorbing surface 821, and the adsorbing surface 821 adsorbs the heat dissipation portion 181 guided by the plurality of guides 84. In this way, the transfer module 82 can hold the heat dissipation connector 18 in the predetermined position on the adsorbing surface 821.

In addition, since the heat dissipation connector 18 can be held in the predetermined position, the transfer module 82 can precisely mount the heat dissipation connector 18 on the semiconductor chip 13 and the lead frame 11 which are placed on the stage 81. That is, the transfer module 82 can locate the heat dissipation connector 18 on the semiconductor chip 13 and the lead frame 11 so that the connecting portion 182 electrically connects the first electrode 131 and the first terminal portion 111.

In this way, the heat dissipation connector 18 can be precisely mounted on the semiconductor chip 13 and the lead frame 11 by using the semiconductor device 80. Consequently, the heat dissipation portion 181 can be located in a desired position. It is therefore possible to improve the manufacturing yield of the semiconductor device 10.

(4) Modified Example

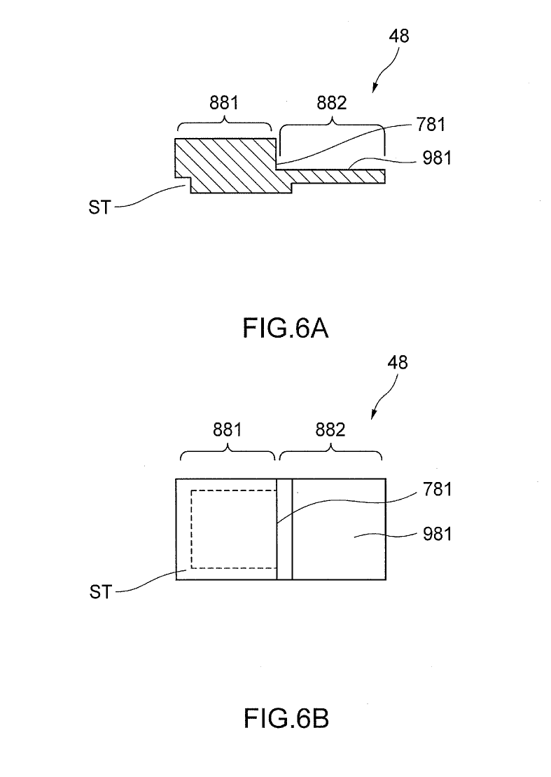

FIGS. 6A and 6B are drawings of a heat dissipation connector 48 of a modified example of the first embodiment.

FIG. 6A illustrates a cross section of the heat dissipation connector 48 as the modified example of the first embodiment, and FIG. 6B illustrates the upper face of the heat dissipation connector 48.

The connecting portion 882 of the heat dissipation connector 48 is a sheet-like portion extending from the side face 781 of the heat dissipation portion 881. Unlike the connecting portion in the first embodiment, the connecting portion 882 is a flat, belt-like sheet having no bent portion. The connecting portion 882 of the modified example can be formed by simultaneously pressing a metal sheet from its upper and lower faces and thereby thinning a part of the metal sheet.

The connecting portion 182 of the first embodiment is formed by bending a part of the metal sheet 40 (see FIGS. 2 and 3). Since it is difficult to precisely bend the metal sheet 40 so as to form a step having a small difference of elevation, a step having a large difference of elevation is formed in the connecting portion 182 of the first embodiment. Accordingly, the upper face of the connecting portion 182 is elevated with respect to the lower face of the heat dissipation connector 18. That is, it is difficult in the first embodiment to suppress the elevation of the upper face of the connecting portion 182.

In contrast, the connecting portion 882 in the modified example is formed by not bending but thinning the part of the connecting portion 882. Accordingly, the upper face 981 of the connecting portion 882 is not significantly elevated with respect to the lower face of the heat dissipation connector 48 as compared with the first embodiment. Consequently, it is possible to suppress the elevation of the upper face 981 of the connecting portion 882.

A decrease in height of the upper face 981 of the connecting portion 882 results in a reduction in height variation of the upper face 981 of the connecting portion 882. Consequently, it is possible to precisely form the heat dissipation connector 48 having a desired shape of the connecting portion 882.

### Second Embodiment

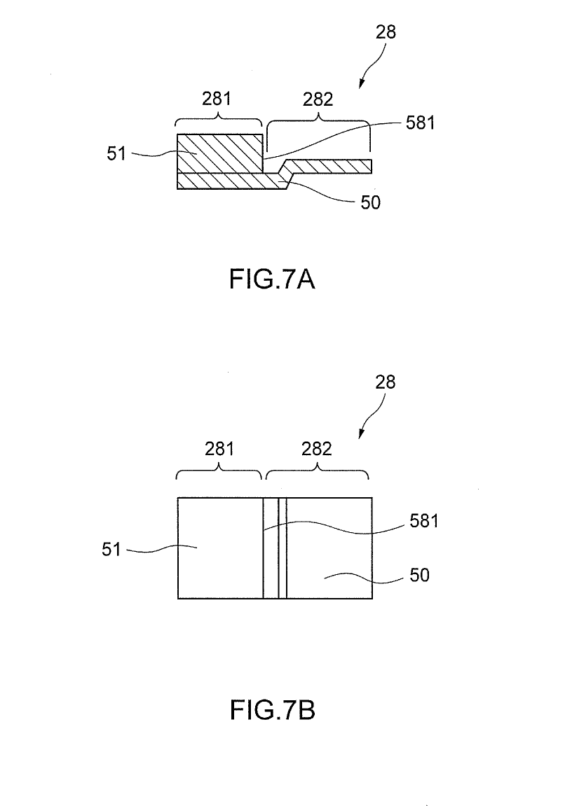

FIGS. 7A and 7B are drawings of a heat dissipation connector 28 of a second embodiment.

FIG. 7A illustrates a cross section of the heat dissipation connector 28 of the second embodiment, and FIG. 7B illustrates the upper face of the heat dissipation connector 28 of the second embodiment.

The heat dissipation connector 28 of the second embodiment differs from the heat dissipation connector of the first embodiment. The heat dissipation connector 28 is made of two different components, i.e., a metal sheet 50 and a metal-plated layer 51. In the second embodiment, the metal-plated layer 51 is formed by means of metal plating. Metal plating allows the thickness of the metal-plated layer 51 to be varied easily. Accordingly, it is possible to form the metal-plated layer 51 having an appropriate thickness on a product-by-product basis. The rest of the configuration of the second embodiment may be the same as the corresponding configuration of the first embodiment.

In addition, the metal sheet 50 and the metal-plated layer 51 are formed of the same metal (for example, copper). In this way, bondability between the metal sheet 50 and the metal-plated layer 51 is enhanced by forming the metal sheet 50 and the metal-plated layer 51 of the same metal. It is therefore possible to efficiently transfer heat from the metal sheet 50 to the metal-plated layer 51. Accordingly, the heat dissipation efficiency of the heat dissipation connector 28 is maintained satisfactorily, even though the heat dissipation connector 28 is made of two components.

(1) Method of Manufacturing Heat Dissipation Connector

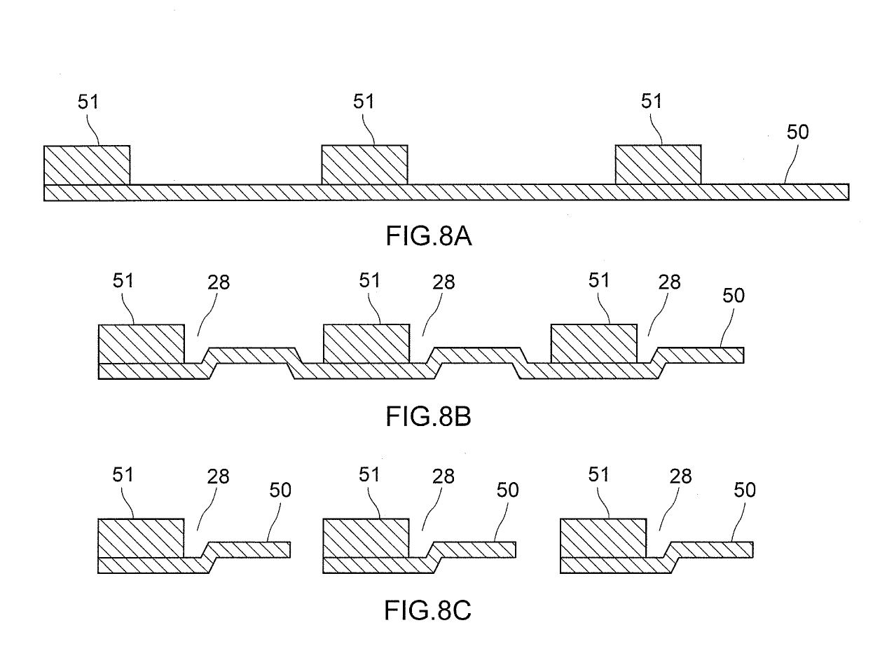

FIGS. 8A to 8C are drawings for describing a method of manufacturing the heat dissipation connector 28 of the second embodiment.

FIGS. 8A to 8C are cross-sectional views in respective steps of the method of manufacturing the heat dissipation connector 28.

First, a mask for covering regions which serve as connecting portions 282 and exposing regions which serve as heat dissipation portions 281 is formed on a metal sheet 50. Next, metal plating is selectively performed, by using the mask, on the regions which serve as the heat dissipation portions 281 of the metal sheet 50 to form metal-plated layers 51. The mask is then removed, so that the structure illustrated in FIG. 8A can be obtained.

Parts of the metal sheet 50 are then pressed to form continuous heat dissipation connectors 28 as illustrated in FIG. 8B.

As illustrated in FIG. 8C, the heat dissipation connectors 28 are then cut apart. The heat dissipation connector 28 of the second embodiment can be obtained in this way.

According to the second embodiment, the metal-plated layer 51 of the heat dissipation connector 28 is formed by means of metal plating. Consequently, it is possible to easily form the metal-plated layer 51 having an appropriate thickness on a product-by-product basis. In addition, according to the second embodiment, the metal sheet 50 and the metal-plated layer 51 are formed of the same metal. Consequently, bondability between the metal sheet 50 and the metal-plated layer 51 is enhanced to maintain excellent thermal conduction from the metal sheet 50 to the metal-plated layer 51.

According to the second embodiment, the heat dissipation portion 281 and the connecting portion 282 are integrated with each other to configure one heat dissipation connector 28, as similar to the first embodiment. It is therefore possible to obtain the same effects as those of the first embodiment.

(2) Modified Example

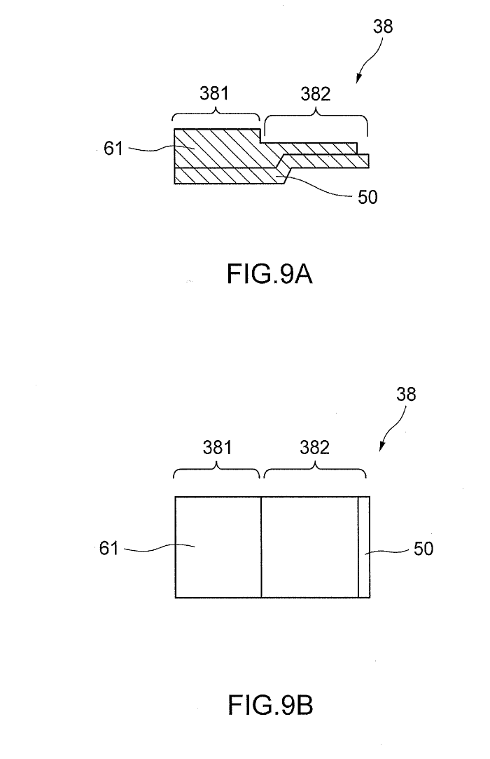

FIGS. 9A and 913 are drawings of a heat dissipation connector 38 of a modified example of the second embodiment.

FIG. 9A illustrates a cross section of the heat dissipation connector 38 as the modified example of the second embodiment, and FIG. 9B illustrates the upper face of the heat dissipation connector 38.

In the heat dissipation connector 38, a metal-plated layer 61 is also formed on a portion serving as a connecting portion 382. Accordingly, the connecting portion 382 is formed to be thicker than the connecting portion 282 of the second embodiment. The connecting portion 382 of the modified example is wider in cross-sectional area than the connecting portion 282 of the second embodiment and has excellent conductive properties. Consequently, according to the modified example, the connecting portion 382 allows the first electrode 131 and the first terminal 111 to be electrically connected with low resistance.

The heat dissipation connector 38 of the modified example can be formed by metal-plating the entire surface of the metal sheet 50 once, and then forming a mask on it to metal-plate again in the manufacturing method of the second embodiment.

While certain embodiments have been described, these embodiments have been presented by way of example only, and are not intended to limit the scope of the inventions. Indeed, the novel connectors, methods, devices and apparatuses described herein may be embodied in a variety of other forms; furthermore, various omissions, substitutions and changes in the form of the connectors, methods, devices and apparatuses described herein may be made without departing from the spirit of the inventions. The accompanying claims and their equivalents are intended to cover such forms or modifications as would fall within the scope and spirit of the inventions.

1. A heat dissipation connector mounted on a semiconductor chip and sealed up with a molding resin along with the semiconductor chip and a lead frame, comprising:
a heat dissipation portion configured to have a block shape, and have an upper face exposed out of the molding resin; and
a connecting portion configured to extend from a first side face of the heat dissipation portion, and electrically connect an electrode arranged on the semiconductor chip to the lead frame,
wherein the heat dissipation portion and the connecting portion are integrally made of the same metal sheet.

2. The connector of claim 1, wherein
the heat dissipation portion has a second side face located on an opposite side of the first side face,
a step is provided on the second side face, and
a lower region of the second side face which is on a side of the semiconductor chip is recessed inward compared with an upper region of the second side face.

3. The connector of claim 1, wherein the connecting portion extends from the first side face to include a bent portion.

4. A heat dissipation connector mounted on a semiconductor chip and sealed up with a molding resin along with the semiconductor chip and a lead frame, comprising:
a heat dissipation portion configured to have a block shape, and have an upper face exposed out of the molding resin; and
a connecting portion configured to extend from a first side face of the heat dissipation portion, and electrically connect an electrode arranged on the semiconductor chip to the lead frame,
wherein
the connector is made of a belt-like metal sheet, and a metal-plated layer disposed on the metal sheet, and
the metal sheet and the metal-plated layer contain the same metal.

5. The connector of claim 4, wherein the heat dissipation portion is made of the metal sheet and the metal-plated layer.

6. The connector of claim 4, wherein the connecting portion is made of only the metal sheet, out of the metal sheet and the metal-plated layer.

7. The connector of claim 4, wherein the connecting portion is made of the metal sheet and the metal-plated layer.

8. The connector of claim 7, wherein a thickness of the metal-plated layer in the connecting portion is smaller than a thickness of the metal-plated layer in the heat dissipation portion.

9. The connector of claim 4, wherein the connecting portion extends from the first side face to include a bent portion.

10. A semiconductor device comprising:
a lead frame;
a semiconductor chip mounted on the lead frame;
a heat dissipation connector mounted on the semiconductor chip; and
a molding resin which seals up the lead frame, the semiconductor chip, and the heat dissipation connector,
the heat dissipation connector comprising:
a heat dissipation portion configured to have a block shape, and have an upper face exposed out of the molding resin; and
a connecting portion configured to extend from a first side face of the heat dissipation portion, and electrically connect an electrode arranged on the semiconductor chip to the lead frame,
wherein the heat dissipation portion and the connecting portion are integrally made of the same metal sheet.

11. The device of claim 10, wherein
the heat dissipation portion has a second side face located on an opposite side of the first side face,
a step is provided on the second side face, and
a lower region of the second side face which is on a side of the semiconductor chip is recessed inward compared with an upper region of the second side face.

12. The device of claim 10, wherein the connecting portion extends from the first side face to include a bent portion.

13. A semiconductor device comprising:
a lead frame;
a semiconductor chip mounted on the lead frame;
a heat dissipation connector mounted on the semiconductor chip; and
a molding resin which seals up the lead frame, the semiconductor chip, and the heat dissipation connector,
the heat dissipation connector comprising:
a heat dissipation portion configured to have a block shape, and have an upper face exposed out of the molding resin; and
a connecting portion configured to extend from a first side face of the heat dissipation portion, and electrically connect an electrode arranged on the semiconductor chip to the lead frame,
wherein
the connector is made of a belt-like metal sheet, and a metal-plated layer disposed on the metal sheet, and
the metal sheet and the metal-plated layer contain the same metal.

14. The device of claim 13, wherein the heat dissipation portion is made of the metal sheet and the metal-plated layer.

15. The device of claim 13, wherein the connecting portion is made of only the metal sheet, out of the metal sheet and the metal-plated layer.

16. The device of claim 13, wherein the connecting portion is made of the metal sheet and the metal-plated layer.

17. The device of claim 16, wherein a thickness of the metal-plated layer in the connecting portion is smaller than a thickness of the metal-plated layer in the heat dissipation portion.

18. A method of manufacturing a heat dissipation connector mounted on a semiconductor chip and sealed up with a molding resin along with the semiconductor chip and the lead frame, comprising:
pressing and cutting a metal sheet to form the heat dissipation connector which includes a heat dissipation portion having a block shape and a connecting portion extending from a first side face of the heat dissipation portion, the heat dissipation portion and the connecting portion being integrally formed.

19. A method of manufacturing a semiconductor device, comprising:
mounting a semiconductor chip on an island portion of a lead frame;
mounting a heat dissipation connector on a surface of the semiconductor chip and on a terminal portion of the lead frame to electrically connect an electrode arranged on the semiconductor chip to the terminal portion via a connecting portion of the heat dissipation connector; and
sealing up the lead frame, the semiconductor chip, and the heat dissipation connector with a molding resin so as to expose an upper face of a heat dissipation portion of the heat dissipation connector out of the molding resin.

20. A semiconductor manufacturing apparatus for mounting a heat dissipation connector on a semiconductor chip, comprising:
a stage configured to hold a lead frame on which the semiconductor chip is mounted; and
a transfer module configured to adsorb the heat dissipation connector to transfer the heat dissipation connector onto the semiconductor chip,
wherein an adsorbing surface of the transfer module has a guide for guiding the heat dissipation connector to a desired position on the adsorbing surface.
